(19) United States
(12) Patent Application Publication
(10) Pub. No.: US 2026/0035789 A1
(43) Pub. Date: Feb. 5, 2026

(54) METHOD AND APPARATUS FOR CONFORMAL BORON DOPING OF THREE-DIMENSIONAL STRUCTURE

(71) Applicants: INSTITUTE OF MICROELECTRONICS, CHINESE ACADEMY OF SCIENCES, Beijing (CN); BEIJING SUPERSTRING ACADEMY OF MEMORY TECHNOLOGY, Beijing (CN)

(72) Inventors: Jianfeng Gao, Beijing (CN); Shuai Yang, Beijing (CN); Jinbiao Liu, Beijing (CN); Weibing Liu, Beijing (CN); Junfeng Li, Beijing (CN); Tao Yang, Beijing (CN); Jun Luo, Beijing (CN); Jinjuan Xiang, Beijing (CN); Guilei Wang, Beijing (CN)

(21) Appl. No.: 19/022,717

(22) Filed: Jan. 15, 2025

(30) Foreign Application Priority Data
Jul. 31, 2024 (CN) 202411043105.5

(51) Int. Cl. C23C 16/455; C23C 16/02; C23C 16/40; C23C 16/52; C23C 16/56

(52) U.S. Cl. CPC C23C 16/45529; C23C 16/02; C23C 16/401; C23C 16/403; C23C 16/45553; C23C 16/52; C23C 16/56

(57) ABSTRACT

A method and an apparatus for conformal boron doping of a three-dimensional structure. The method comprises: removing an oxide layer from a surface of a silicon-based three-dimensional (3D) substrate; forming, after removing the oxide layer, a first group of stacked films on a surface of the silicon-based three-dimensional substrate; forming a second group of stacked films on a surface of the first group of stacked films away from the silicon-based 3D substrate; depositing an aluminum oxide passivation layer on a surface of the second group of stacked films away from the first group of stacked films; and boron-doping the silicon-based 3D substrate through laser annealing or rapid thermal annealing, where the laser annealing or the rapid thermal annealing drives boron dopants, which comprises boron oxide, into the silicon-based 3D substrate via an auxiliary layer.

This application claims priority to Chinese Patent Application No. 202411043105.5, titled “METHOD FOR CONFORMAL BORON DOPING OF THREE-DIMENSIONAL STRUCTURE AND APPLICATION THEREOF,” filed on Jul. 31, 2024 with the China National Intellectual Property Administration, which is incorporated herein by reference in its entirety.

### FIELD

The present disclosure relates to the technical field of semiconductor manufacturing, and in particular to a method and an apparatus for conformal boron doping of a three-dimensional structure.

### BACKGROUND

Semiconductor devices are shirking. Novel three-dimensional (3D) structures, such as FinFET, nanowires, 3DDRAM, etc., are utilized for manufacturing integrated circuits to improve performance and a degree of integration of the semiconductor devices. These 3D structures bring great challenges to traditional ion implantation techniques for ultra-shallow silicon doping. Structural damages, a channel effect, and a shadow effect would occur when implanting ions into 3D structures. Hence, new techniques need to be developed as replacement of the traditional ion implantation or traditional doping.

Some doping methods have been proposed to address the above limitations. Plasma doping was investigated in order to overcome limitations of conventional implantation. However, problematic damage-related phenomena including transient enhanced diffusion (TED) during dopant activation cannot be fully avoided. The spin-on doping (SOD) cannot be applied directly on the 3D structures. The monolayer doping, the vapor-phase doping using BBr₃, and the like have unsatisfactory performances in controlled deposition of dopant sources.

Atomic layer deposition (ALD) features in good conformality, good uniformity, and controllable atomic-scale thickness, because ALD process is controlled by self-limiting surface reactions. Boron doping using ALD may have potential to achieve uniform and conformal doping in 3D nanoscale electronic devices.

In conventional technology, B₂O₃ is deposited through plasma-enhanced ALD to implement doping. In one aspect, B₂O₃ is apt to absorb water vapor. When exposed to ambient air and contacting water vapor, B₂O₃ would form volatile H₃BO₃ and thus degrade. In another aspect, nucleation is difficult when depositing B₂O₃ on a surface of silicon through thermal ALD, and hence B₂O₃ may not form a film after reaching a certain thickness.

Hence, it is necessary to select suitable boron source precursors and oxidants to achieve controllable growth of a boron oxide film, and it is necessary to provide a suitable stable surface passivation layer, which can protect B₂O₃ from damages through in-situ deposition, to achieve damage-free doping diffusion. In addition, the plasma-enhanced ALD cannot achieve conformal deposition, because it is also subject to the shadow effect when depositing materials on 3D structures, and it also introduces plasma damage. Hence, the plasma-enhanced ALD cannot meet requirements of devices.

### SUMMARY

A method and an apparatus for conformal boron doping of a three-dimensional structure are provided according to embodiments of the present disclosure. Unlike plasma-enhanced atomic layer deposition (ALD), there is no shadow effect during deposition on the three-dimensional structure, and thus conformal deposition can be achieved. Moreover, there is no structural damage due to plasma.

In a first aspect, a method for conformal boron doping of a three-dimensional structure is provided according to an embodiment of the present disclosure. The method comprises: removing an oxide layer from a surface of a silicon-based three-dimensional (3D) substrate; forming, after removing the oxide layer, a first group of stacked films on a surface of the silicon-based three-dimensional substrate; forming a second group of stacked films on a surface of the first group of stacked films away from the silicon-based 3D substrate; depositing an aluminum oxide passivation layer on a surface of the second group of stacked films away from the first group of stacked films; and boron-doping the silicon-based 3D substrate through laser annealing or rapid thermal annealing, where the laser annealing or the rapid thermal annealing drives boron dopants, which comprises boron oxide, into the silicon-based 3D substrate via an auxiliary layer.

In an embodiment, the first group of stacked films comprises at least one silicon oxide layer and at least one boron oxide layer arranged which are interleaved with each other, and the second group of stacked films comprises at least one aluminum oxide layer and another at least one boron oxide layer which are interleaved with each other.

In an embodiment, removing the oxide layer from the surface of the silicon-based 3D substrate comprises: cleaning the surface of the silicon-based 3D substrate using diluted hydrofluoric acid (DHF); placing, after the cleaning, the silicon-based 3D substrate on a base within a chamber for ALD; processing the silicon-based 3D substrate on the base for duration ranging from 20s to 40s using a mixed gas of HF and NH₃, where the chamber is evacuated and the base is heated to a temperature ranging from 35° C. to 40° C. before the preprocessing; and baking, after the processing the silicon-based 3D substrate using the mixed gas, the silicon-based 3D substrate in a hydrogen atmosphere at a temperature ranging from 150° C. to 200° C. for duration ranging from 40s to 80s.

In an embodiment, a ratio of hydrofluoric acid to water in the DHF is 1:100. The low concentration of hydrofluoric acid leads to a low etching rate, and thus a native oxide film on the surface of the substate can be removed preliminarily.

Afterwards, the silicon-based 3D substrate is disposed in the chamber of an ALD device, and the chamber is evacuated. The temperature of the base in the chamber is controlled to be in a range of 35° C. to 40° C. The substrate is then processed with the mixed gas of HF and NH₃ for the duration ranging from 20s to 40s. Afterwards, the substrate is heated to the temperature ranging from 150° C. to 200° C. and baked under the hydrogen atmosphere for the duration ranging from 40s to 80s. Thereby, the native oxide layer on the surface of the silicon substrate, and the above etching processing has high selectivity against the silicon substrate and a SiN film. Then, the wafer may be baked through heating, such that impurities and defects on the surface of the substrate can be reduced. Thereby, the surface of the substrate is exceptionally clean, and conductivity of the silicon substate is improved due to low concentration of impurities and high electron mobility.

In an embodiment, forming the first group of stacked films on the surface of the silicon-based three-dimensional substrate comprises: introducing pulses of a silicon-based compound gas and pulses a first boron-based compound gas alternately into a chamber for ALD to form the first group of stacked films on the surface of the silicon-based 3D substrate.

After the native oxide has been removed from the surface of the silicon-based 3D substrate, the first group of stacked films is deposited on the surface of the silicon-based 3D substrate, such that that nucleation and deposition of boron oxide can occur on the surface. Materials of the first group of stacked films comprise silicon oxide and boron oxide. Hence, the first group of stacked films can effectively eliminate or slow down diffusion of other metal ions, which comes from subsequent group of stacked oxide films, into the substrate. That is, a concentration of another metal ion from the second group of stacked films can be reduced in the silicon substrate after the boron doping.

In an embodiment, forming the first group of stacked films on the surface of the silicon-based three-dimensional substrate comprises: transferring, in vacuum, the silicon-based 3D substrate into the chamber for ALD; forming a silicon oxide layer on the surface of the silicon-based 3D substrate through first processing cycles while controlling the chamber at a temperature ranging from 250° C. to 300° C., where: each first processing cycle comprises introducing a pulse of silanediamine (a.k.a., bis(diethylamino)silane, or BDEAS) and then introducing a first pulse of ozone into the chamber; in each first processing cycle, duration of the pulse of silanediamine ranges from 0.1s to 0.5s, the chamber is evacuated for duration ranging from 0.2s to 3s after the pulse of silanediamine, duration of the first pulse of ozone ranges from 0.2s to 3s, and the chamber is evacuated for duration ranging from 0.2s to 3s after the first pulse of ozone; and a quantity of the first processing cycles ranges from 10 to 25; and forming a first boron oxide layer on a surface of the silicon oxide layer away from the silicon-based 3D substrate through second processing cycles, where: each second processing cycle comprises introducing a first pulse of trimethyl borate in situ and then introducing a second pulse of ozone into the chamber; in each second processing cycle, duration of the first pulse of trimethyl borate ranges from 0.1s to 0.5s, the chamber is evacuated for duration ranging from 0.2s to 3s after the first pulse of trimethyl borate, duration of the second pulse of ozone ranges from 0.5s to 3s, and the chamber is evacuated for duration ranging from 0.2s to 3s after the second pulse of ozone; and a quantity of the second processing cycles ranges from 5 to 25.

In an embodiment, the forming of the silicon oxide layer and the forming of the first boron oxide layer are alternately repeated according to a 3D structure and a requirement on doping to form the first group of stacked films. For example, a thickness of the first group of stacked films may be controlled in a range from 0.5 nm to 3 nm.

In an embodiment, forming the second group of stacked films on the surface of the first group of stacked films away from the silicon-based 3D substrate comprises: introducing pulses of an aluminum-based compound gas and pulses a second boron-based compound gas alternately into a chamber for ALD to form the second group of stacked films on the surface of the first group of stacked films away from the silicon-based 3D substrate.

After the first group of stacked films has been formed on the surface of the silicon-based 3D substrate, the second group of stacked films is further deposited on the surface of the first group of stacked films. Thereby, a thickness of dopant oxide films and boron content in the films can be well controlled. Materials of the second group of stacked films comprise aluminum oxide and boron oxide. The second group of stacked films is configured to finely control a thickness and the boron content of the films. A final effect of the boron doping can be accurately adjusted through the thickness and the boron content.

In an embodiment, forming the second group of stacked films on the surface of the first group of stacked films away from the silicon-based 3D substrate comprises: forming an aluminum oxide layer on the surface of the first group of stacked films through one or more third processing cycles while controlling the chamber at a temperature ranging from 80° C. to 150° C., where: each third processing cycle comprises introducing a first pulse of trimethyl aluminum and then introducing a third pulse of ozone into the chamber; and in each third processing cycle, duration of the first pulse of trimethyl aluminum ranges from 0.1s to 0.15s, the chamber is evacuated for duration ranging from 0.2s to 3s after the first pulse of trimethyl aluminum, duration of the third pulse of ozone ranges from 0.2s to 3s, and the chamber is evacuated for duration ranging from 0.2s to 3s after the third pulse of ozone; and forming a second boron oxide layer on a surface of the aluminum oxide layer away from the first group of stacked films through fourth processing cycles, where: each fourth processing cycle comprises introducing a second pulse of trimethyl borate in situ and then introducing a fourth pulse of ozone into the chamber; in each fourth processing cycle, duration of the second pulse of trimethyl borate ranges from 0.1s to 0.5s, the chamber is evacuated for duration ranging from 0.2s to 3s after the second pulse of trimethyl borate, duration of the fourth pulse of ozone ranges from 0.5s to 3s, and the chamber is evacuated for duration ranging from 0.2s to 3s after the fourth pulse of ozone; and a quantity of the fourth processing cycles ranges from 10 to 20.

In an embodiment, the forming of the aluminum oxide layer and the forming of the second boron oxide layer are alternately repeated according to a 3D structure and a requirement on doping to form the second group of stacked films.

Herein the trimethyl borate serve as a source of boron (i.e., a boron precursor) when the depositing boron oxide, and the ozone serves as oxidant, which effectively addresses difficulties of nucleation and incapability of forming a film exceeding a certain thickness in depositing boron oxide through thermal ALD on a silicon surface.

Herein a surface of the topmost boron oxide layer in the second group of stacked films may be covered with the passivation layer made of aluminum oxide, such that the boron oxide layer is protected from being damaged. In an embodiment, the passivation layer is formed through fifth processing cycles. Each fifth processing cycle comprises introducing a second pulse of trimethyl aluminum and then introducing a fifth pulse of ozone into the chamber. In each fifth processing cycle, duration of the second pulse of trimethyl aluminum ranges from 0.1s to 0.15s, the chamber is evacuated for duration ranging from 0.5s to 1.5s after the second pulse of trimethyl aluminum, duration of the fifth pulse of ozone ranges from 0.5s to 1.5s, and the chamber is evacuated for duration ranging from Is to 3s after the fifth pulse of ozone. A quantity of the fifth processing cycles ranges from 3 to 5. Hence, the stable passivation layer of a certain thickness can be obtained.

In an embodiment, the laser annealing utilizes a layer of which wavelength ranges from 308 nm to 10.6 um and an energy density ranges from 200 mj/cm² to 2 j/cm², an annealing temperature of the laser annealing ranges from 900° C. to 1100° C., and duration of the laser annealing ranges from 10 ns to 1 ms.

In an embodiment, a temperature ramp rate of the rapid thermal annealing is greater than 250° C./s, and duration of the rapid thermal annealing ranges from 5s to 30s.

During the laser annealing, a high-energy laser beam irradiates the substrate, and it energy is absorbed by the substrate and converted into heat, which increases a local temperature at the irradiated part of the substrate very high. In such case, boron atoms at the irradiated part diffuse into a lattice of the substrate and occupy a position as replacement, and hence they are activated. Then, the lattice is cooled down rapidly and the atoms in the lattice are rearranged, and hence the silicon substrate is doped with boron dopants. That is, with high accuracy, the dopants are activated, and the defects are eliminated.

In an embodiment, after the boron dopants comprising boron oxide are driven into the silicon substrate via the auxiliary layer(s) through the laser annealing or the rapid thermal annealing, the residual boron oxide thin films and aluminum oxide thin films is removed using a solution of hydrofluoric acid. Concentration of hydrofluoric acid in the solution is not limited herein, and appropriate concentration of hydrofluoric acid may be selected for the removal on requirement.

In a second aspect, an apparatus for conformal boron doping of a 3D structure is provided according to another embodiment of the present disclosure. The apparatus is configured to implement any foregoing method.

Herein the first group of stacked films and the second group of stacked films are sequentially formed on the surface of the silicon-based 3D substrate in sequence. The first group of stacked films is configured to eliminate or slow down the diffusion of other metal ions, which come from subsequent group of stacked oxide films, into the substrate. That is, it is configured to reduce the doping concentration of another metal ion, which comes from the second group of stacked films, in the silicon substrate. The second group of stacked films is configured to control the thickness and the boron content of the dopant oxide films. The aluminum oxide passivation layer covers the surface of the second group of stacked films, and then the boron dopants in boron oxide are driven into the silicon-based 3D substrate via the auxiliary layer(s) through the laser annealing or the rapid thermal annealing. Hence, the silicon-based 3D substrate is doped, that is, boron doping on the 3D structure is achieved. In one aspect, a suitable boron source precursor and a suitable oxidant are selected to address the difficulties of nucleation of boron oxide and incapability of forming a boron oxide film exceeding a certain thickness. In another aspect, aluminum oxide serves as the passivation layer protecting the boron oxide films from being damaged, and hence damage-free diffusion doping can be achieved using the laser annealing or the rapid thermal annealing. Addressed is the issue that conformal deposition on 3D structures cannot be achieved using plasma-enhanced ALD due to a shadow effect and the issue that structural damages are induced due to plasma.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIG. 1 is a flow chart of a method for conformal boron doping of a three-dimensional (3D) structure according to an embodiment of the present disclosure.

FIG. 2 is a schematic diagram showing a part of a first group of stacked films on a surface of a silicon-based 3D substrate according to an embodiment of the present disclosure.

FIG. 3 is a schematic diagram showing a part of a second group of stacked films on a surface of the first group of stacked films away from the silicon-based 3D substrate according to an embodiment of the present disclosure.

FIG. 4 is a schematic diagram showing a part of an aluminum oxide passivation layer covering a surface of the second group of stacked films away from the first group of stacked films according to an embodiment of the present disclosure.

FIG. 5 is a graph of depth distribution of boron dopants according to an embodiment of the present disclosure.

FIG. 6 a graph of depth distribution of boron dopants according to a comparison example of the present disclosure.

Reference numerals:

| | |
|---|---|
| 1: first group of stacked films, | 2: second group of stacked films, |
| 3: aluminum oxide passivation layer. | |

### DETAILED DESCRIPTION OF EMBODIMENTS

Hereinafter illustrative description is provided for further details of the present disclosure. Unless otherwise specified, all technical and scientific terms used herein have the same meaning which is understood by those skilled in the art to which the present disclosure pertains.

Terms used herein are only for describing specific embodiments of the present disclosure, not for limiting the embodiments. Unless clearly indicated otherwise in the context, the singular form may refer to a plurality. In addition, herein the terms “comprise” and/or “include” indicate existence of concerning feature(s), step(s), operation(s), device(s), component(s), and/or combinations of the above.

Hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

### First Embodiment

A method for conformal boron doping of a three-dimensional (3D) structure is provided according to an embodiment of the present disclosure. The method comprises steps S11 to S16.

In step S11, a native oxide layer was removed from a silicon-based 3D substrate using a solution of hydrofluoric acid and water, of which a ratio is 1:100. Then, the silicon-based 3D substrate was placed on a base in a first chamber of an atomic layer deposition (ALD) device. The first chamber was then evacuated. A temperature of the base was controlled to be 35° C. Afterwards, the silicon-based 3D substrate was processed using a mixed gas of HF and NH₃ for 30s. Then, the silicon-based 3D substrate was heated to 180° C. and baked for 1 min. Thereby, the oxide layer on a surface of the substrate can be removed.

In step S12, the silicon-based 3D substrate is transferred in vacuum into a second chamber of the ALD device. A temperature of the second chamber was controlled to be 270° C. In a first cycle, a pulse of silanediamine (of which a source temperature was 26° C.) with duration of 0.3s was introduced into the second chamber, then the second chamber was evacuated for 2s, then a pulse of ozone with duration of 2s was introduced into the second chamber, and then the second chamber was evacuated for 2s. The first cycle is repeated for 15 cycles to form a silicon oxide layer on the surface of the silicon-based 3D substrate.

Afterwards, in a second cycle, a pulse of trimethyl borate (of which a source temperature was 21° C.) with duration of 0.3s was introduced into the second chamber, then the second chamber was evacuated for 2s, then a pulse of ozone with duration of 2s was introduced into the second chamber, and then the second chamber was evacuated for 2s. The second cycle is repeated for 20 cycles to form a boron oxide layer on the surface of the silicon oxide layer away from the silicon-based 3D substrate.

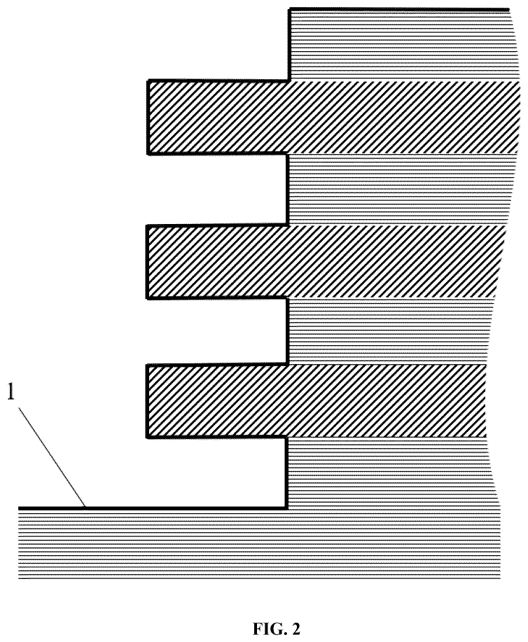

Formation of the silicon oxide layer and formation of the boron oxide layer may be alternately repeated according to a 3D structure on the substrate and a requirement on the boron doping to form the first group of stacked films, as shown in FIG. 2.

In step S13, a temperature of a third chamber (which may be the second chamber) in which the substrate is located was controlled to be 100° C. In a third cycle, a pulse of trimethyl aluminum (of which a source temperature was 21° C.) with duration 0.12s was introduced into the third chamber, then the third chamber was evacuated for 2s, then a pulse of ozone with duration of 2s was introduced into the third chamber, and then the third chamber was evacuated for 2s. The third cycle may be repeated for one or more cycles. Hence, an aluminum oxide layer is formed on the surface of the first group of stacked films.

Afterwards, in a fourth cycle, a pulse of trimethyl borate (of which a source temperature was 21° C.) with duration of 0.3s was introduced in-situ into the third chamber, then the third chamber was evacuated for 2s, then a pulse of ozone with duration of 2s was introduced into the third chamber, and then the third chamber was evacuated for 2s. The fourth cycle was repeated for 15 cycles to form a boron oxide layer on the surface of the aluminum oxide layer away from the first group of stacked films.

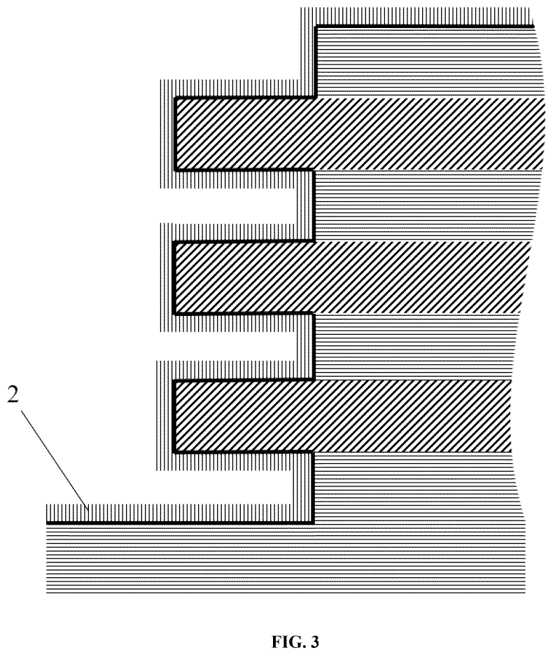

Formation of the aluminum oxide layer and formation of the boron oxide layer may be alternately repeated according to a 3D structure on the substrate and a requirement on the boron doping to form the second group of stacked films, as shown in FIG. 3.

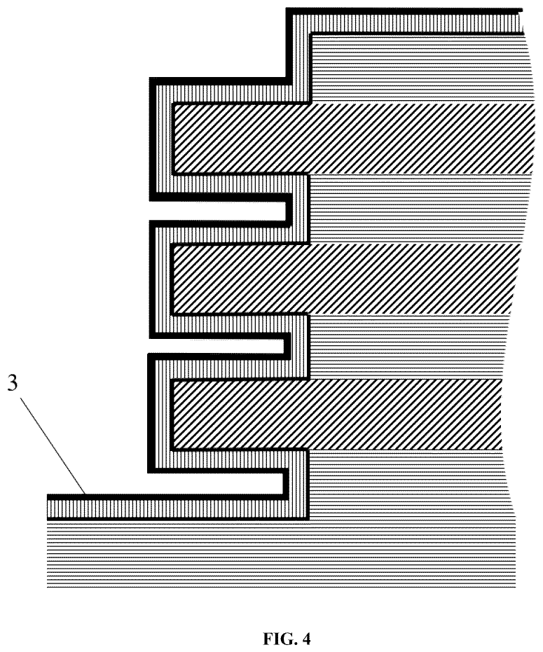

In step S14, in a fifth cycle, a pulse of trimethyl aluminum (of which a source temperature was 21° C.) with duration of 0.125s was introduced in-situ into a fourth chamber (which may be the third chamber) in which the substrate is located, then the fourth chamber was evacuated for Is, then a pulse of the ozone with duration of Is was introduced into the fourth chamber, and then the fourth chamber was evacuated for 2s. The fifth cycle was repeated for 4 cycles to form an aluminum oxide passivation layer on the surface of the second group of stacked films away from the first group of stacked films, as shown in FIG. 4.

In step S15, the substrate having the first and second groups of thin films and the passivation layer was annealed using laser having wavelength ranging from 308 nm to 10.6 um and an energy density of 1 j/cm². Temperature of the annealing was controlled to be 1000° C., duration of the annealing was 500 ns. The annealing drives the boron dopants, which comprise boron oxide, into the silicon-based 3D substrate via the auxiliary layer(s), e.g., the aluminum oxide layer(s). Hence, the silicon-based 3D substrate was doped.

In step S16, the remaining boron oxide and the aluminum oxide thin film were removed using a hydrofluoric acid solution.

### Second Embodiment

A method for conformal boron doping of a three-dimensional (3D) structure is provided according to an embodiment of the present disclosure. The method comprises steps S21 to S26.

In step S21, a native oxide layer was removed from a silicon-based 3D substrate using a solution of hydrofluoric acid and water, of which a ratio is 1:100. Then, the silicon-based 3D substrate was placed on a base in a first chamber of an atomic layer deposition (ALD) device. The first chamber was then evacuated. A temperature of the base was controlled to be 35° C. Afterwards, the silicon-based 3D substrate was processed using a mixed gas of HF and NH₃ for 20s. Then, the silicon-based 3D substrate was heated to 200° C. and baked for 40s. Thereby, the native oxide layer on a surface of the substrate can be removed.

In step S22, the silicon-based 3D substrate is transferred in vacuum into a second chamber of the ALD device. A temperature of the second chamber was controlled to be 250° C. In a first cycle, a pulse of silanediamine (of which a source temperature was 26° C.) with duration of 0.5s was introduced into the second chamber, then the second chamber was evacuated for 0.2s, then a pulse of ozone with duration of 0.2s was introduced into the second chamber, and then the second chamber was evacuated for 0.2s. The first cycle is repeated for 25 cycles to form a silicon oxide layer on the surface of the silicon-based 3D substrate.

Afterwards, in a second cycle, a pulse of trimethyl borate (of which a source temperature was 21° C.) with duration of 0.1s was introduced into the second chamber, then the second chamber was evacuated for 0.2s, then a pulse of ozone with duration of 0.5s was introduced into the second chamber, and then the second chamber was evacuated for 0.2s. The second cycle is repeated for 25 cycles to form a boron oxide layer on the surface of the silicon oxide layer away from the silicon-based 3D substrate.

Formation of the silicon oxide layer and formation of the boron oxide layer may be alternately repeated according to a 3D structure on the substrate and a requirement on the boron doping to form the first group of stacked films.

In step S23, a temperature of a third chamber (which may be the second chamber) in which the substrate is located was controlled to be 80° C. In a third cycle, a pulse of trimethyl aluminum (of which a source temperature was 21° C.) with duration 0.15s was introduced into the third chamber, then the third chamber was evacuated for 0.2s, then a pulse of ozone with duration of 0.2s was introduced into the third chamber, and then the third chamber was evacuated for 0.2s. The third cycle may be repeated for one or more cycles. Hence, an aluminum oxide layer is formed on the surface of the first group of stacked films.

Afterwards, in a fourth cycle, a pulse of trimethyl borate (of which a source temperature was 21° C.) with duration of 0.1s was introduced in-situ into the third chamber, then the third chamber was evacuated for 0.2s, then a pulse of ozone with duration of 0.2s was introduced into the third chamber, and then the third chamber was evacuated for 0.2s. The fourth cycle was repeated for 20 cycles to form a boron oxide layer on the surface of the aluminum oxide layer away from the first group of stacked films.

Formation of the aluminum oxide layer and formation of the boron oxide layer may be alternately repeated according to a 3D structure on the substrate and a requirement on the boron doping to form the second group of stacked films.

In step S24, in a fifth cycle, a pulse of trimethyl aluminum (of which a source temperature was 21° C.) with duration of 0.15s was introduced in-situ into a fourth chamber (which may be the third chamber) in which the substrate is located, then the fourth chamber was evacuated for 0.5s, then a pulse of the ozone with duration of 0.5s was introduced into the fourth chamber, and then the fourth chamber was evacuated for Is. The fifth cycle was repeated for 3 cycles to form an aluminum oxide passivation layer on the surface of the second group of stacked films away from the first group of stacked films.

In step S15, the substrate having the first and second groups of thin films and the passivation layer was annealed using laser having wavelength ranging from 308 nm to 10.6 um and an energy density of 2 j/cm². Temperature of the annealing was controlled to be 900° C., duration of the annealing was Ims. The annealing drives the boron dopants, which comprise boron oxide, into the silicon-based 3D substrate via the auxiliary layers. Hence, the silicon-based 3D substrate was doped.

In step S26, the remaining boron oxide and the aluminum oxide thin film were removed using a hydrofluoric acid solution.

### Third Embodiment

A method for conformal boron doping of a three-dimensional (3D) structure is provided according to an embodiment of the present disclosure. The method comprises steps S31 to S36.

In step S31, a native oxide layer was removed from a silicon-based 3D substrate using a solution of hydrofluoric acid and water, of which a ratio is 1:100. Then, the silicon-based 3D substrate was placed on a base in a first chamber of an atomic layer deposition (ALD) device. The first chamber was then evacuated. A temperature of the base was controlled to be 35° C. Afterwards, the silicon-based 3D substrate was processed using a mixed gas of HF and NH₃ for 40s. Then, the silicon-based 3D substrate was heated to 150° C. and baked for 80s. Thereby, the native oxide layer on a surface of the substrate can be removed.

In step S32, the silicon-based 3D substrate is transferred in vacuum into a second chamber of the ALD device. A temperature of the second chamber was controlled to be 300° C. In a first cycle, a pulse of silanediamine (of which a source temperature was 26° C.) with duration of 0.1s was introduced into the second chamber, then the second chamber was evacuated for 3s, then a pulse of ozone with duration of 3s was introduced into the second chamber, and then the second chamber was evacuated for 3s. The first cycle is repeated for 10 cycles to form a silicon oxide layer on the surface of the silicon-based 3D substrate.

Afterwards, in a second cycle, a pulse of trimethyl borate (of which a source temperature was 21° C.) with duration of 0.5s was introduced into the second chamber, then the second chamber was evacuated for 3s, then a pulse of ozone with duration of 3s was introduced into the second chamber, and then the second chamber was evacuated for 3s. The second cycle is repeated for 5 cycles to form a boron oxide layer on the surface of the silicon oxide layer away from the silicon-based 3D substrate.

Formation of the silicon oxide layer and formation of the boron oxide layer may be alternately repeated according to a 3D structure on the substrate and a requirement on the boron doping to form the first group of stacked films.

In step S33, a temperature of a third chamber (which may be the second chamber) in which the substrate is located was controlled to be 150° C. In a third cycle, a pulse of trimethyl aluminum (of which a source temperature was 21° C.) with duration 0.1s was introduced into the third chamber, then the third chamber was evacuated for 3s, then a pulse of ozone with duration of 3s was introduced into the third chamber, and then the third chamber was evacuated for 3s. The third cycle may be repeated for one or more cycles. Hence, an aluminum oxide layer is formed on the surface of the first group of stacked films.

Afterwards, in a fourth cycle, a pulse of trimethyl borate (of which a source temperature was 21° C.) with duration of 0.5s was introduced in-situ into the third chamber, then the third chamber was evacuated for 3s, then a pulse of ozone with duration of 3s was introduced into the third chamber, and then the third chamber was evacuated for 3s. The fourth cycle was repeated for 15 cycles to form a boron oxide layer on the surface of the aluminum oxide layer away from the first group of stacked films.

Formation of the aluminum oxide layer and formation of the boron oxide layer may be alternately repeated according to a 3D structure on the substrate and a requirement on the boron doping to form the second group of stacked films.

In step S34, in a fifth cycle, a pulse of trimethyl aluminum (of which a source temperature was 21° C.) with duration of 0.125s was introduced in-situ into a fourth chamber (which may be the third chamber) in which the substrate is located, then the fourth chamber was evacuated for 1s, then a pulse of the ozone with duration of Is was introduced into the fourth chamber, and then the fourth chamber was evacuated for 2s. The fifth cycle was repeated for 4 cycles to form an aluminum oxide passivation layer on the surface of the second group of stacked films away from the first group of stacked films.

In step S35, the substrate having the first and second groups of thin films and the passivation layer was annealed using rapid thermal annealing (RTA). A temperature ramp rate of the RTA was controlled to be 300° C./s, duration of the RTA was 20s. The annealing drives the boron dopants, which comprise boron oxide, into the silicon-based 3D substrate via the auxiliary layers. Hence, the silicon-based 3D substrate was doped.

In step S36, the remaining boron oxide and the aluminum oxide thin film were removed using a hydrofluoric acid solution.

### Fourth Embodiment

A method for conformal boron doping of a three-dimensional (3D) structure is provided according to an embodiment of the present disclosure. The method comprises steps S41 to S46.

In step S41, a native oxide layer was removed from a silicon-based 3D substrate using a solution of hydrofluoric acid and water, of which a ratio is 1:100. Then, the silicon-based 3D substrate was placed on a base in a first chamber of an atomic layer deposition (ALD) device. The first chamber was then evacuated. A temperature of the base was controlled to be 35° C. Afterwards, the silicon-based 3D substrate was processed using a mixed gas of HF and NH₃ for 30s. Then, the silicon-based 3D substrate was heated to 180° C. and baked for 1 min. Thereby, the native oxide layer on a surface of the substrate can be removed.

In step S42, the silicon-based 3D substrate is transferred in vacuum into a second chamber of the ALD device. A temperature of the second chamber was controlled to be 280° C. In a first cycle, a pulse of silanediamine (of which a source temperature was 26° C.) with duration of 0.4s was introduced into the second chamber, then the second chamber was evacuated for 1s, then a pulse of ozone with duration of 2s was introduced into the second chamber, and then the second chamber was evacuated for 2s. The first cycle is repeated for 20 cycles to form a silicon oxide layer on the surface of the silicon-based 3D substrate.

Afterwards, in a second cycle, a pulse of trimethyl borate (of which a source temperature was 21° C.) with duration of 0.2s was introduced into the second chamber, then the second chamber was evacuated for Is, then a pulse of ozone with duration of 2s was introduced into the second chamber, and then the second chamber was evacuated for 2s. The second cycle is repeated for 15 cycles to form a boron oxide layer on the surface of the silicon oxide layer away from the silicon-based 3D substrate.

Formation of the silicon oxide layer and formation of the boron oxide layer may be alternately repeated according to a 3D structure on the substrate and a requirement on the boron doping to form the first group of stacked films.

In step S43, a temperature of a third chamber (which may be the second chamber) in which the substrate is located was controlled to be 120° C. In a third cycle, a pulse of trimethyl aluminum (of which a source temperature was 21° C.) with duration 0.1s was introduced into the third chamber, then the third chamber was evacuated for Is, then a pulse of ozone with duration of 1.5s was introduced into the third chamber, and then the third chamber was evacuated for 2s. The third cycle may be repeated for one or more cycles. Hence, an aluminum oxide layer is formed on the surface of the first group of stacked films.

Afterwards, in a fourth cycle, a pulse of trimethyl borate (of which a source temperature was 21° C.) with duration of 0.3s was introduced in-situ into the third chamber, then the third chamber was evacuated for 2s, then a pulse of ozone with duration of 2s was introduced into the third chamber, and then the third chamber was evacuated for 2s. The fourth cycle was repeated for 15 cycles to form a boron oxide layer on the surface of the aluminum oxide layer away from the first group of stacked films.

Formation of the aluminum oxide layer and formation of the boron oxide layer may be alternately repeated according to a 3D structure on the substrate and a requirement on the boron doping to form the second group of stacked films.

In step S44, in a fifth cycle, a pulse of trimethyl aluminum (of which a source temperature was 21° C.) with duration of 0.15s was introduced in-situ into a fourth chamber (which may be the third chamber) in which the substrate is located, then the fourth chamber was evacuated for 1.5s, then a pulse of the ozone with duration of 1.5s was introduced into the fourth chamber, and then the fourth chamber was evacuated for 2s. The fifth cycle was repeated for 4 cycles to form an aluminum oxide passivation layer on the surface of the second group of stacked films away from the first group of stacked films.

In step S45, the substrate having the first and second groups of thin films and the passivation layer was annealed using rapid thermal annealing (RTA). A temperature ramp rate of the RTA was controlled to be 300° C./s, duration of the RTA was 30s. The annealing drives the boron dopants, which comprise boron oxide, into the silicon-based 3D substrate via the auxiliary layers. Hence, the silicon-based 3D substrate was doped.

In step S46, the remaining boron oxide and the aluminum oxide thin film were removed using a hydrofluoric acid solution.

### First Comparison Example

A method for boron doping of a three-dimensional (3D) structure is provided as an comparison example. The method comprises steps S1 to S6.

In step S1, a native oxide layer was removed from a silicon-based 3D substrate using a solution of hydrofluoric acid and water, of which a ratio is 1:100. Then, the silicon-based 3D substrate was placed on a base in a first chamber of an atomic layer deposition (ALD) device. The first chamber was then evacuated. A temperature of the base was controlled to be 35° C. Afterwards, the silicon-based 3D substrate was processed using a mixed gas of HF and NH₃ for 30s. Then, the silicon-based 3D substrate was heated to 180° C. and baked for 1 min. Thereby, the native oxide layer on a surface of the substrate can be removed.

In step S2, the silicon-based 3D substrate is transferred in vacuum into a second chamber of the ALD device. A temperature of the second chamber was controlled to be 120° C. A pulse of trimethyl aluminum (of which a source temperature was 21° C.) with duration of 0.3s was introduced into the second chamber, then the second chamber was evacuated for 2s, then a pulse of ozone with duration of 2s was introduced into the second chamber, and then the second chamber was evacuated for 2s. Thereby, an aluminum oxide layer is formed on the surface of the silicon-based 3D substrate.

In step S3, in a first cycle, a pulse of trimethyl borate (of which a source temperature was 21° C.) with duration of 0.3s was introduced into the second chamber, then the second chamber was evacuated for 2s, then a pulse of ozone with duration of 2s was introduced into the second chamber, and then the second chamber was evacuated for 2s. The first cycle was repeated for 15 cycles to form a boron oxide layer on the surface of the aluminum oxide auxiliary layer.

In step S4, in a second cycle, a pulse of trimethyl aluminum (of which a source temperature was 21° C.) with duration of 0.125s was introduced in-situ into the second chamber, then the second chamber was evacuated for Is, then a pulse of the ozone with duration of Is was introduced into the second chamber, and then the second chamber was evacuated for 2s. The second cycle was repeated for 4 cycles to form an aluminum oxide passivation layer covering the surface of the boron oxide layer.

In step S5, the boron dopants, which comprise boron oxide, are driven into the silicon-based substrate via the auxiliary layer using laser annealing or RTA. Hence, the silicon-based 3D substrate was doped.

In step S6, the remaining boron oxide and the aluminum oxide thin film were removed using a hydrofluoric acid solution.

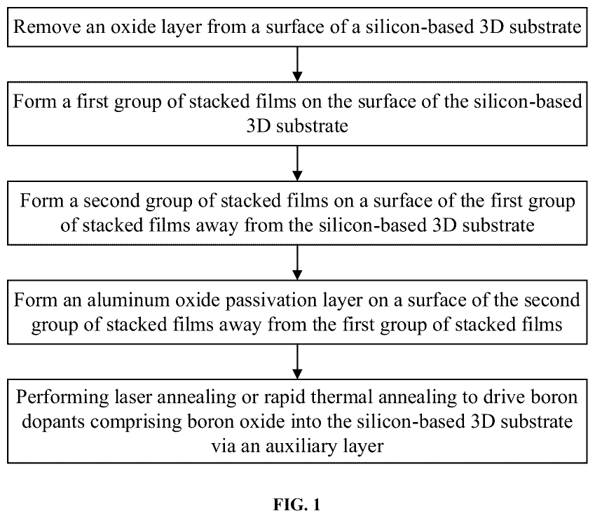

FIG. 1 is a flow chart of a method for conformal boron doping of a 3D structure according to an embodiment of the present disclosure.

Hereinafter provided are specifications of four samples fabricated under difference processing conditions on a basis of the method as shown in the first embodiment.

Each sample comprises a 2 nm SiBO film (i.e., the first group of stack films) and a BAlO film (i.e., the second group of stacked films). The SiBO film is fabricated under 270° C. and comprises 4 silicon oxide (SiO) layers and 4 boron oxides (BO) layer that are alternately arranged. In the SiBO film, each SiO layer is fabricated through 15 ALD cycles, each BO layer is fabricated through 20 ALD cycles, and a total thickness of one SiO layer and one BO layer is approximately 0.6 nm. Then, an aluminum oxide (AlO) layer is fabricated through one ALD cycle on the SiBO film. Afterwards, the chamber is cooled down to 100° C., and a BO layer is fabricated through 15 ALD cycles. Then, the BAlO film is fabricated and comprises n AlO layers and n BO layers that are alternately arranged, where n is a positive integral. In the BAlO film, each ALO layer is fabricated through one ALD cycle, each BO layer is fabricated through 15 ALD cycles, and a total thickness of one AlO layer and one BO layer is approximately 0.9 nm. Afterwards, another single AlO layer is fabricated on the BAlO film. In the above films, each ALD cycle of SiO refers to “a Is pulse of silanediamine, then 3s evacuation, then a 2s pulse of ozone, and then 5s evacuation”, each ALD cycle of ALO layer refers to “a 0.125s pulse of trimethyl aluminum, then Is evacuation, then a 2s pulse of ozone borate, and then 6s evacuation”, and each ALD cycle of BO layer refers to “a 0.25s pulse of trimethyl borate, then 3s evacuation, then a Is pulse of ozone borate, and then 2s evacuation”.

The four samples differ from each other in the value of n and correspond to n=3, n=6, n=9, and n=12, respectively. Accordingly, they are denoted as “3Cycle”, “5Cycle”, “9Cycle”, and “12Cycle”, respectively. In the sample 3Cycle, a thickness of the SiBO film is approximately 2 nm, a thickness of the BAlO film is approximately 2.5 nm, a total thickness of the two is approximately 5 nm, and after the annealing, an atomic ratio of the boron dopants is 0.62%. In the sample 6Cycle, a thickness of the SiBO film is approximately 2 nm, a thickness of the BAlO film is approximately 5 nm, a total thickness of the two is approximately 6 nm, and after the annealing, an atomic ratio of the boron dopants is 0.69%. In the sample 9Cycle, a thickness of the SiBO film is approximately 2 nm, a thickness of the BAlO film is approximately 7.5 nm, a total thickness of the two is approximately 8 nm, and after the annealing, an atomic ratio of the boron dopants is 0.74%. In the sample 12Cycle, a thickness of the SiBO film is approximately 2 nm, a thickness of the BAlO film is approximately 10 nm, a total thickness of the two is approximately 5 nm, and after the annealing, an atomic ratio of the boron dopants is 0.76%.

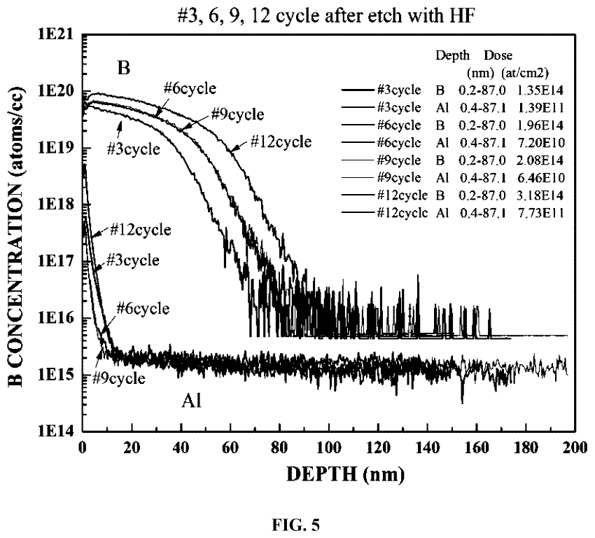

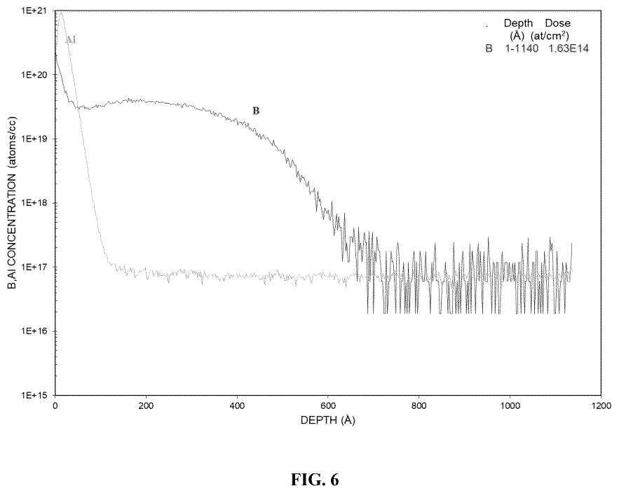

The above results including FIG. 5 and FIG. 6 show that the concentration of boron dopants in the samples of the first embodiment can reach 8E+19, while that in the sample of the first comparison example is 3E+19. Hence, the conformal boron doping of the 3D structure provided herein achieves a doping level approximating the plasma-enhanced ALD that deposits B₂O₃ for doping. The above results also show that the concentration of boron dopants can adjusted through changing the thickness of the second group of stacked films. Concentration of aluminum atoms in the silicon-based 3D substrate is also effectively controlled.

As described above, the above embodiments are only intended to describe the technical solutions of the present disclosure, and not to limit the present disclosure. Although the present disclosure is described in detail with reference to the above embodiments, those skilled in the art should understand that, modifications can be made to the technical solutions recorded in the above embodiments, or equivalent replacements can be made to some of the technical features thereof, and the modifications and the replacements will not make the corresponding technical solutions deviate from the spirit and the scope of the technical solutions of the embodiments of the present disclosure.

1. A method for conformal boron doping of a 3D structure, comprising:
removing an oxide layer from a surface of a silicon-based three-dimensional (3D) substrate;
forming, after removing the oxide layer, a first group of stacked films on a surface of the silicon-based three-dimensional substrate;
forming a second group of stacked films on a surface of the first group of stacked films away from the silicon-based 3D substrate;
depositing an aluminum oxide passivation layer on a surface of the second group of stacked films away from the first group of stacked films; and
boron-doping the silicon-based 3D substrate through laser annealing or rapid thermal annealing, wherein the laser annealing or the rapid thermal annealing drives boron dopants, which comprises boron oxide, into the silicon-based 3D substrate via an auxiliary layer;
wherein the first group of stacked films comprises at least one silicon oxide layer and at least one boron oxide layer arranged which are interleaved with each other, and the second group of stacked films comprises at least one aluminum oxide layer and another at least one boron oxide layer which are interleaved with each other.

2. The method according to claim 1, wherein removing the oxide layer from the surface of the silicon-based 3D substrate comprises:
cleaning the surface of the silicon-based 3D substrate using diluted hydrofluoric acid (DHF);
placing, after the cleaning, the silicon-based 3D substrate on a base within a chamber for ALD;
processing the silicon-based 3D substrate on the base for duration ranging from 20s to 40s using a mixed gas of HF and NH₃, wherein the chamber is evacuated and the base is heated to a temperature ranging from 35° C. to 40° C. before the preprocessing; and
baking, after the processing the silicon-based 3D substrate using the mixed gas, the silicon-based 3D substrate in a hydrogen atmosphere at a temperature ranging from 150° C. to 200° C. for duration ranging from 40s to 80s.

3. The method according to claim 1, wherein forming the first group of stacked films on the surface of the silicon-based three-dimensional substrate comprises:
introducing pulses of a silicon-based compound gas and pulses a first boron-based compound gas alternately into a chamber for ALD to form the first group of stacked films on the surface of the silicon-based 3D substrate.

4. The method according to claim 1, wherein forming the second group of stacked films on the surface of the first group of stacked films away from the silicon-based 3D substrate comprises:
introducing pulses of an aluminum-based compound gas and pulses a second boron-based compound gas alternately into a chamber for ALD to form the second group of stacked films on the surface of the first group of stacked films away from the silicon-based 3D substrate.

5. The method according to claim 3, wherein forming the first group of stacked films on the surface of the silicon-based three-dimensional substrate comprises:
transferring, in vacuum, the silicon-based 3D substrate into the chamber for ALD;
forming a silicon oxide layer on the surface of the silicon-based 3D substrate through first processing cycles while controlling the chamber at a temperature ranging from 250° C. to 300° C., wherein:
each first processing cycle comprises introducing a pulse of silanediamine and then introducing a first pulse of ozone into the chamber;
in each first processing cycle, duration of the pulse of silanediamine ranges from 0.1s to 0.5s, the chamber is evacuated for duration ranging from 0.2s to 3s after the pulse of silanediamine, duration of the first pulse of ozone ranges from 0.2s to 3s, and the chamber is evacuated for duration ranging from 0.2s to 3s after the first pulse of ozone; and
a quantity of the first processing cycles ranges from 10 to 25; and
forming a first boron oxide layer on a surface of the silicon oxide layer away from the silicon-based 3D substrate through second processing cycles, wherein:
each second processing cycle comprises introducing a first pulse of trimethyl borate in situ and then introducing a second pulse of ozone into the chamber;
in each second processing cycle, duration of the first pulse of trimethyl borate ranges from 0.1s to 0.5s, the chamber is evacuated for duration ranging from 0.2s to 3s after the first pulse of trimethyl borate, duration of the second pulse of ozone ranges from 0.5s to 3s, and the chamber is evacuated for duration ranging from 0.2s to 3s after the second pulse of ozone; and
a quantity of the second processing cycles ranges from 5 to 25,
wherein the forming of the silicon oxide layer and the forming of the first boron oxide layer are alternately repeated according to a 3D structure and a requirement on doping to form the first group of stacked films.

6. The method according to claim 4, forming the second group of stacked films on the surface of the first group of stacked films away from the silicon-based 3D substrate comprises:
forming an aluminum oxide layer on the surface of the first group of stacked films through one or more third processing cycle while controlling the chamber at a temperature ranging from 80° C. to 150° C., wherein:
each third processing cycle comprises introducing a first pulse of trimethyl aluminum and then introducing a third pulse of ozone into the chamber; and
in each third processing cycle, duration of the first pulse of trimethyl aluminum ranges from 0.1s to 0.15s, the chamber is evacuated for duration ranging from 0.2s to 3s after the first pulse of trimethyl aluminum, duration of the third pulse of ozone ranges from 0.2s to 3s, and the chamber is evacuated for duration ranging from 0.2s to 3s after the third pulse of ozone; and
forming a second boron oxide layer on a surface of the aluminum oxide layer away from the first group of stacked films through fourth processing cycles, wherein:
each fourth processing cycle comprises introducing a second pulse of trimethyl borate in situ and then introducing a fourth pulse of ozone into the chamber;
in each fourth processing cycle, duration of the second pulse of trimethyl borate ranges from 0.1s to 0.5s, the chamber is evacuated for duration ranging from 0.2s to 3s after the second pulse of trimethyl borate, duration of the fourth pulse of ozone ranges from 0.5s to 3s, and the chamber is evacuated for duration ranging from 0.2s to 3s after the fourth pulse of ozone; and
a quantity of the fourth processing cycles ranges from 10 to 20,
wherein the forming of the aluminum oxide layer and the forming of the second boron oxide layer are alternately repeated according to a 3D structure and a requirement on doping to form the second group of stacked films.

7. The method according to claim 1, wherein depositing the aluminum oxide passivation layer on the surface of the second group of stacked films away from the first group of stacked films comprises:
forming the passivation layer through fifth processing cycles, wherein:
each fifth processing cycle comprises introducing a second pulse of trimethyl aluminum and then introducing a fifth pulse of ozone into the chamber;
in each fifth processing cycle, duration of the second pulse of trimethyl aluminum ranges from 0.1s to 0.15s, the chamber is evacuated for duration ranging from 0.5s to 1.5s after the second pulse of trimethyl aluminum, duration of the fifth pulse of ozone ranges from 0.5s to 1.5s, and the chamber is evacuated for duration ranging from 1s to 3s after the fifth pulse of ozone; and
a quantity of the fifth processing cycles ranges from 3 to 5.

8. The method according to claim 1, wherein:
the laser annealing utilizes a layer of which wavelength ranges from 308 nm to 10.6 um and an energy density ranges from 200 mj/cm² to 2 j/cm², an annealing temperature of the laser annealing ranges from 900° C. to 1100° C., and duration of the laser annealing ranges from 10 ns to 1 ms.

9. The method according to claim 1, wherein:
a temperature ramp rate of the rapid thermal annealing is greater than 250° C./s, and duration of the rapid thermal annealing ranges from 5s to 30s.

10. The method according to claim 1, further comprising:
after the boron-doping, removing the at least one boron oxide layer and the at least one aluminum oxide layer, which remain on the silicon-based 3D substrate, using a solution of hydrofluoric acid.

11. An apparatus for conformal boron doping of a 3D structure, comprising:
a memory storing computer instructions, and
a processor, wherein the processor when executing the computer instructions enables the apparatus to perform:
removing an oxide layer from a surface of a silicon-based three-dimensional (3D) substrate;
forming, after removing the oxide layer, a first group of stacked films on a surface of the silicon-based three-dimensional substrate;
forming a second group of stacked films on a surface of the first group of stacked films away from the silicon-based 3D substrate;
depositing an aluminum oxide passivation layer on a surface of the second group of stacked films away from the first group of stacked films; and
boron-doping the silicon-based 3D substrate through laser annealing or rapid thermal annealing, wherein the laser annealing or the rapid thermal annealing drives boron dopants, which comprises boron oxide, into the silicon-based 3D substrate via an auxiliary layer;
wherein the first group of stacked films comprises at least one silicon oxide layer and at least one boron oxide layer arranged which are interleaved with each other, and the second group of stacked films comprises at least one aluminum oxide layer and another at least one boron oxide layer which are interleaved with each other.
